(19) United States
(12) Patent Application Publication
(10) Pub. No.: US 2021/0043761 A1
(43) Pub. Date: Feb. 11, 2021

(54) DETECTOR BASED ON GALLIUM NITRIDE-BASED ENHANCEMENT-MODE DEVICE AND MANUFACTURING METHOD THEREOF

(71) Applicant: INSTITUTE OF MICROELECTRONICS CHINESE ACADEMY OF SCIENCES, Beijing (CN)

(72) Inventors: Sen HUANG, Beijing (CN); Xinhua WANG, Beijing (CN); Ke WEI, Beijing (CN); Xinyu LIU, Beijing (CN); Wen SHI, Beijing (CN)

(73) Assignee: INSTITUTE OF MICROELECTRONICS CHINESE ACADEMY OF SCIENCES, Beijing (CN)

(21) Appl. No.: 16/868,708

(22) Filed: May 7, 2020

(30) Foreign Application Priority Data
Aug. 8, 2019 (CN) 201910732534.6

(51) Int. Cl. H01L 29/778; H01L 29/20; H01L 29/66; G01N 27/414

(52) U.S. Cl. CPC H01L 29/7786; G01N 27/414; H01L 29/66462; H01L 29/2003

(57) ABSTRACT

A detector based on a gallium nitride-based enhancement-mode device and a manufacturing method thereof. The detector is a gas or solution detector. When the detector is used in electrolyte solution detection, electrolyte solution is located in the gate opening region and directly contacts the thin barrier layer to form a contact interface. The electrolyte solution affects interface charges at the contact interface, leading to a change in a concentration of the two-dimensional electron gas, and further a change in a current between the source and the drain. When the detector is used in a hydrogen-containing gas detection, the H concentration of the hydrogen-containing gas affects interface charges at the contact interface between the gate and the thin barrier layer, leading to a change in a concentration of the two-dimensional electron gas, and further a change in the current between the source and the drain.

This application claims priority of Chinese Patent Application No. 201910732534.6, filed on Aug. 8, 2019, entitled “DETECTOR BASED ON GALLIUM NITRIDE-BASED ENHANCEMENT-MODE DEVICE AND MANUFACTURING METHOD THEREOF”, which is incorporated herein in its entirety by reference.

### TECHNICAL FIELD

The present disclosure generally relates to the technical field of detectors, and more particularly, to a detector based on a gallium nitride-based enhancement-mode device and a manufacturing method thereof.

### BACKGROUND

Group III nitrides, which are wide band gap semiconductor materials, have high breakdown voltage, high temperature resistance, and good abilities of resisting corrosion and radiation. They are ideal materials for manufacturing high-sensitivity detectors. They may be used in physical and biochemical detections such as an electrolyte solution detection, a hazardous gas detection, biomedicine, and the like.

### SUMMARY

At present, conventional group III nitride detectors are depletion-mode high-electron-mobility transistors (HEMT) based on AlGaN/GaN heterostructure materials. However, the background current of the depletion-mode device is large, which results in a detector that not only consumes large power, but also has low sensitivity.

### (1) Technical Problems to be Solved

The present disclosure provides a detector based on, for example, a gallium nitride-based enhancement-mode device to at least partially solve one or more technical problems.

### (2) Technical Solutions

According to an aspect of the disclosure, there is provided a detector based on a gallium nitride-based enhancement-mode device, comprising: a substrate; a thin barrier heterojunction epitaxial on the substrate and comprising from bottom to top a GaN buffer layer and a thin barrier layer, a two-dimensional electron gas existing at an interface of the thin barrier heterojunction; a passivation layer formed on the thin barrier heterojunction and comprising several spaced apart opening regions, the opening regions comprising a source opening region, a drain opening region, and a gate opening region; a source formed in the source opening region and in contact with the thin barrier layer at its bottom; a drain formed in the drain opening region and in contact with the thin barrier layer at its bottom; and a protective layer formed on the source, the drain and the passivation layer; wherein, when the detector is used in an electrolyte solution detection, the electrolyte solution is located in the gate opening region and directly contacts the thin barrier layer to form a contact interface, interface charges at which are affected by the electrolyte solution, leading to a change in a concentration of the two-dimensional electron gas, and further a change in a current between the source and the drain.

According to another aspect of the disclosure, there is provided a detector based on a gallium nitride-based enhancement-mode device, comprising: a substrate; a thin barrier heterojunction epitaxial on the substrate and comprising from bottom to top a GaN buffer layer and a thin barrier layer; a passivation layer formed on the thin barrier heterojunction and comprising several spaced apart opening regions, the opening regions comprising a source opening region, a drain opening region, and a gate opening region; a source formed in the source opening region and in contact with the thin barrier layer at its bottom; a drain formed in the drain opening region and in contact with the thin barrier layer at its bottom; a protective layer formed on the source, the drain and the passivation layer; and a gate filled in the gate opening region and extending onto the protective layer, the gate in contact with the thin barrier layer at its bottom and having a material capable of having a catalytic reaction with a hydrogen-containing gas and forming a Schottky contact with the thin barrier layer.

In an embodiment, the detector may be used to detect a H concentration of a hydrogen-containing gas under extreme environments at high temperature and low temperature. For example, the ambient temperature is below 900° C.

In an embodiment, interface charges at a contact interface between the gate and the thin barrier layer are affected by the H concentration of the hydrogen-containing gas, leading to a change in a concentration of the two-dimensional electron gas, and further a change in a current between the source and the drain.

In an embodiment, the gate is a monolayer film formed by any selected from: Pt, IrPt, PdAg, Au, Pd, Cu, Cr or Ni, or a multilayer metal film formed by any combination selected therefrom.

In an embodiment, in the detectors mentioned above, the thin barrier layer is formed by a material of Al(In, Ga)N, comprising any selected from: an AlGaN or AlInN ternary alloy layer, or an AlInGaN quaternary alloy layer; and/or the thin barrier layer has a thickness of 0-10 nm.

In an embodiment, when the thin barrier layer is an AlGaN ternary alloy layer, an Al composition is fixed and is between 0% and 100%, or the Al composition gradually decreases from y₁% down to x₁%, along from the bottom to the top of the thin barrier layer, where x₁ and y₁ are between 0 and 100; or

when the thin barrier layer is an AlInN ternary alloy layer, the Al composition is fixed and is between 75% and 90%, or the Al composition gradually decreases from y₂% down to x₂%, along from the bottom to the top of the thin barrier layer, where x₂ and y₂ are between 0 and 100; or

when the thin barrier layer is an AlInGaN quaternary alloy layer, the respective composition of Al, In, and Ga is fixed or changed.

In an embodiment, in the detectors mentioned above, the gate opening region is arranged at any position between the source and the drain, and the position of the gate opening region does not affect detection performance.

In an embodiment, an electrolyte solution detection comprises, but not limited to, a detection scenario comprising: environmental water quality monitoring, detection of a pH value, a concentration or an anion-cation concentration of the electrolyte solution, detection of an ion concentration in food, which comprises an iodine concentration detection, or active ions detection in biomedicine.

According to still another aspect of the disclosure, there is provided a method for manufacturing a detector, the method comprising:

preparing a substrate;

manufacturing a thin barrier heterojunction, which is epitaxial on the substrate and comprises from bottom to top a GaN buffer layer and a thin barrier layer;

manufacturing a passivation layer, which is formed on the thin barrier heterojunction and comprises several spaced apart opening regions, the opening regions comprising a source opening region, a drain opening region and a gate opening region;

manufacturing a source, which is formed in the source opening region and is in contact with the thin barrier layer at its bottom;

manufacturing a drain, which is formed in the drain opening region and is in contact with the thin barrier layer at its bottom; and

manufacturing a protective layer, which is formed on the source, the drain and the passivation layer,

wherein a two-dimensional electron gas exists at an interface of the thin barrier heterojunction except for the gate opening region, and

wherein, when the detector is used in an electrolyte solution detection, electrolyte solution is located in the gate opening region and directly contacts the thin barrier layer to form a contact interface, interface charges at which are affected by the electrolyte solution, leading to a change in a concentration of the two-dimensional electron gas, and further a change in a current between the source and the drain.

In an embodiment, the method comprises:

preparing a substrate;

epitaxial growing, on the substrate, a thin barrier heterojunction which comprises from bottom to top a GaN buffer layer and a thin barrier layer;

forming a passivation layer on the thin barrier heterojunction;

etching the passivation layer to form spaced apart source opening and drain opening regions;

forming a source in the source opening region, the source in contact with the thin barrier layer at its bottom;

forming a drain in the drain opening region, the drain in contact with the thin barrier layer at its bottom;

forming a protective layer on the source, the drain and the passivation layer; and

etching the protective layer and the passivation layer below in the region between the source and the drain, to form a gate opening region, wherein a two-dimensional electron gas exists at an interface of the thin barrier heterojunction except for the gate opening region.

According to still another aspect of the disclosure, there is provided a method for manufacturing a detector, the method comprising:

preparing a substrate;

manufacturing a thin barrier heterojunction, which is epitaxial on the substrate and comprises from bottom to top a GaN buffer layer and a thin barrier layer;

manufacturing a passivation layer, which is formed on the thin barrier heterojunction and comprises several spaced apart opening regions, the opening regions comprising a source opening region, a drain opening region and a gate opening region, wherein a two-dimensional electron gas exists at an interface of the thin barrier heterojunction except for the gate opening region;

manufacturing a source, which is formed in the source opening region and is in contact with the thin barrier layer at its bottom;

manufacturing a drain, which is formed in the drain opening region and is in contact with the thin barrier layer at its bottom;

manufacturing a protective layer, which is formed on the source, the drain and the passivation layer; and

manufacturing a gate, which is filled in the gate opening region and extends onto the protective layer, and the gate is in contact with the thin barrier layer at its bottom and has a material capable of having a catalytic reaction with a hydrogen-containing gas and forming a Schottky contact with the thin barrier layer.

In an embodiment, the method comprises:

preparing a substrate;

epitaxial growing, on the substrate, a thin barrier heterojunction which comprises from bottom to top a GaN buffer layer and a thin barrier layer;

forming a passivation layer on the thin barrier heterojunction;

etching the passivation layer to form spaced apart source opening and drain opening regions;

forming a source in the source opening region, the source in contact with the thin barrier layer at its bottom;

forming a drain in the drain opening region, the drain in contact with the thin barrier layer at its bottom;

forming a protective layer on the source, the drain and the passivation layer;

etching the protective layer and the passivation layer below in the region between the source and the drain, to form a gate opening region, wherein a two-dimensional electron gas exists at an interface of the thin barrier heterojunction except for the gate opening region; and

forming a gate in the gate opening region, the gate being filled in the gate opening region and extending onto the protective layer, and the gate in contact with the thin barrier layer at its bottom and having a material capable of having a catalytic reaction with a hydrogen-containing gas and forming a Schottky contact with the thin barrier layer.

### (3) Beneficial Effects

The detector based on the gallium nitride-based enhancement-mode device and the manufacturing method thereof provided by the disclosure, as can be seen from above technical solutions, has one or more beneficial effects:

1. For example, it may not be necessary to manufacture a gate in a gate opening region within the detector used in an electrolyte solution detection. The gate opening region of the detector is exposed. When the detector is used in the electrolyte solution detection, the electrolyte solution is located in the gate opening region and directly contacts the thin barrier layer to form a contact interface. The electrolyte solution affects interface charges at the contact interface, leading to a change in a concentration of a two-dimensional electron gas at the interface of the thin barrier heterojunction, further leading to a significant change in a current between the source and the drain, thereby a highly sensitive solution detection can be achieved. A high density of positive charges may be induced on the surface of the thin barrier layer, and the concentration of the two-dimensional electron gas in the channel except for the gate opening region may be significantly enhanced, by arranging a passivation layer. At the same time, a protective layer formed on the source, the drain and the passivation layer may prevent the electrolyte solution from reacting with electrodes or the passivation layer, and prevent the electrodes from being corroded. Therefore, the device may be reused multiple times and the reliability of the device is improved.

2. In the detector structure, the gate opening region may be arranged at any position between the source and the drain, which is different from the arrangement in existing enhancement-mode devices, where the gate is arranged closer to the source (relative to the drain). There is no need to consider an arrangement of the position of the gate opening region. The detection performance will not be affected whether the position of the gate opening region is close to the source or the drain, or in the middle, between the source and the drain.

3. The detector may be used for monitoring environmental water quality, detecting a pH value, detecting a concentration or detecting an anion-cation concentration of electrolyte solution. It has higher sensitivity than traditional pH test papers and may be reused. It may also be used for detecting an ion concentration in food, such as an iodine concentration detection, detecting active ions in biomedicine, or the like.

4. In the detector used for detecting a hydrogen-containing gas (e.g., a hydrogen-containing dangerous gas), the material of the gate is capable of having a catalytic reaction with hydrogen-containing gas and forming a Schottky contact with the thin barrier layer. The H concentration of the hydrogen-containing gas affects interface charges at the contact interface between the gate and the thin barrier layer, leading to a change in the concentration of the two-dimensional electron gas, and further leading to a significant change in the current between the source and the drain. The detector may detect the H concentration of hydrogen-containing gas under extreme environments at high temperature and low temperature, and presents higher sensitivity and repeatability than traditional depleted devices.

5. Compared with traditional semiconductor detectors, the solution detector or gas detector based on the GaN-based enhancement-mode device proposed in the disclosure can have higher detection sensitivity and lower power consumption, and may be manufactured in one molding and used repeatedly.

### BRIEF DESCRIPTION OF THE DRAWINGS

FIG. 1 is a schematic diagram of the structure of a detector based on a gallium nitride-based enhancement-mode device according to a first embodiment of the present disclosure.

FIG. 2 is a schematic diagram of using the detector shown in FIG. 1 in an electrolyte solution detection.

FIG. 3 is a schematic diagram of the structure of the detector based on a gallium nitride-based enhancement-mode device according to a second embodiment of the present disclosure

FIG. 4 is a schematic diagram of using the detector shown in FIG. 3 in a concentration detection of a hydrogen-containing gas.

FIGS. 5 to 8 are schematic diagrams of respective steps corresponding to a method for manufacturing the detector shown in the first embodiment according to a third embodiment of the present disclosure.

FIGS. 5 to 9 are schematic diagrams of respective steps corresponding to a method for manufacturing the detector shown in the second embodiment according to a fourth embodiment of the present disclosure.

FIG. 5 is a schematic diagram of a structure after an epitaxial structure, which includes from bottom to top a substrate, a GaN buffer layer, a thin barrier layer, and a passivation layer, is fabricated.

FIG. 6 is a schematic diagram of a structure after the passivation layer in the epitaxial structure is etched to form spaced apart source opening and drain opening regions, and a source and a drain are fabricated in the source opening region and the drain opening region, respectively.

FIG. 7 is a schematic diagram of a structure forming a protective layer on the source, the drain, and the passivation layer.

FIG. 8 is a schematic diagram of a structure of etching the protective layer and the passivation layer therebelow in the region between the source and the drain and forming the gate opening region.

FIG. 9 is a schematic diagram of a structure after a gate is formed in the gate opening region.

### SYMBOL DESCRIPTION

1—solution detector;
1′—gas detector;
11—substrate;
12—GaN buffer layer;
13—thin barrier layer;
14—two-dimensional electron gas;
15—passivation layer;
161—source;
162—drain;
17—protective layer;
18—gate opening region;
19—gate;
2—electrolyte solution.

### DETAILED DESCRIPTION

To make the objectives, technical solutions, and advantages of the present disclosure more apparent, the present disclosure will be further described in detail below in conjunction with specific embodiments and with reference to the accompanying drawings.

The present disclosure provides a detector based on a gallium nitride-based enhancement-mode device and a method for manufacturing the same. Compared with an existing detector based on a depletion-mode device, it overcome one or more technical defects of an existing detector, that is, for example, the background current of the existing detector is large, resulting in a detector that not only consumes large power but also presents low sensitivity. The detector of the present disclosure may be used in detection of a concentration of a hydrogen-containing gas in harsh environments, environmental water quality monitoring, detection of a pH value and/or a concentration, detection of an ion concentration in food, and/or active ion detection in biomedicine. Compared with a conventional semiconductor detector, the detector based on the GaN-based enhancement-mode device disclosed in the present disclosure can have higher detection sensitivity and/or lower power consumption, and the device may be manufactured in one molding and/or used repeatedly.

### First Embodiment

In a first exemplary embodiment of the present disclosure, a detector based on a gallium nitride-based enhancement-mode device is provided. The detector is a solution detector 1.

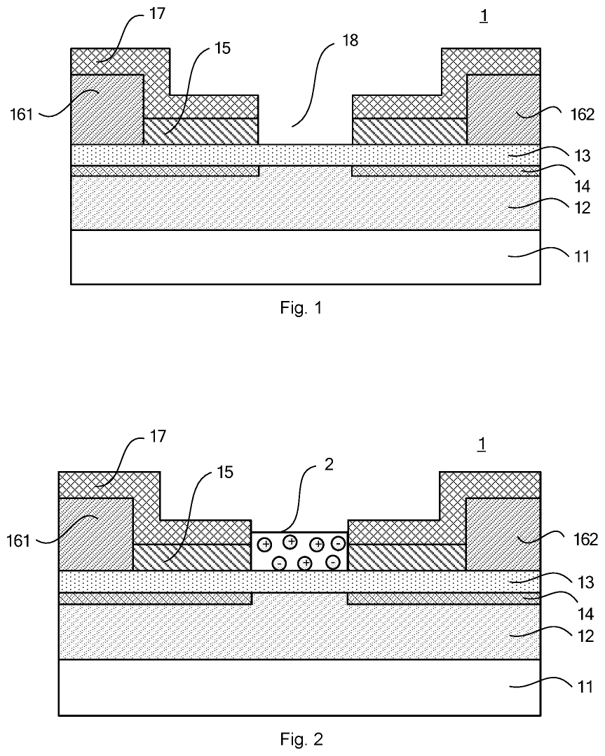

FIG. 1 is a schematic diagram of a structure of a detector based on a gallium nitride-based enhancement-mode device according to a first embodiment of the present disclosure. FIG. 2 is a schematic diagram of using the detector shown in FIG. 1 in an electrolyte solution detection.

Refer to FIG. 1 and FIG. 2, the detector based on a gallium nitride-based enhancement-mode device of the present disclosure includes: a substrate; a thin barrier heterojunction epitaxial on the substrate and comprising from bottom to top a GaN buffer layer and a thin barrier layer, wherein a two-dimensional electron gas exists at an interface of the thin barrier heterojunction; a passivation layer formed on the thin barrier heterojunction and comprising several spaced apart opening regions, the opening regions comprising a source opening region, a drain opening region and a gate opening region; a source formed in the source opening region and in contact with the thin barrier layer at its bottom; a drain formed in the drain opening region and in contact with the thin barrier layer at its bottom; and a protective layer formed on the source, the drain and the passivation layer; wherein, when the detector is used in an electrolyte solution detection, the electrolyte solution is located in the gate opening region and directly contacts the thin barrier layer to form a contact interface, interface charges at which are affected by the electrolyte solution, leading to a change in a concentration of the two-dimensional electron gas, and further a change in a current between the source and the drain.

In the embodiment, as shown in FIG. 1, the detector is a solution detector 1, including a substrate 11, a GaN buffer layer 12, a thin barrier layer 13, a passivation layer 15, a source 161, a drain 162, and a protective layer 17.

The GaN buffer layer 12 and the thin barrier layer 13 form a thin barrier heterojunction, and a two-dimensional electron gas 14 exists at the interface of the thin barrier heterojunction.

In the embodiment, the thin barrier layer 13 has a material of Al(In, Ga)N, including any one selected from: an AlGaN or AlInN ternary alloy layer, or an AlInGaN quaternary alloy layer. In an embodiment, the thickness of the thin barrier layer 13 is 0 to 10 nm; alternatively, the thickness of the thin barrier layer 13 is 0 to 6 nm; further, the thickness of the thin barrier layer 13 is 0 to 5 nm.

In an embodiment, when the thin barrier layer 13 is an AlGaN ternary alloy layer, an Al composition is fixed and is between 0% and 100%. Alternatively, the Al composition gradually decreases from y₁% down to x₁%, along from the bottom to the top of the thin barrier layer 13 (along an up-down direction indicated in the drawing), where x₁ and y₁ are between 0 and 100.

When the thin barrier layer 13 is an AlInN ternary alloy layer, the Al composition is fixed and is between 75% and 90%. Alternatively, the Al composition gradually decreases from y₂% down to x₂%, along from the bottom to the top of the thin barrier layer 13, where x₂ and y₂ are between 0 and 100.

When the thin barrier layer 13 is an AlInGaN quaternary alloy layer, the respective composition of Al, In, and Ga is fixed or changed.

In the AlₘGa₁₋ₘN or AlₙIn₁₋ₙN ternary alloy layer, the Al composition corresponds to m and n, respectively. In the AlₚInₚGa_{1-p-q}N quaternary alloy layer, the respective composition of Al, In and Ga is p, q, 1-p-q.

In the embodiment, the passivation layer 15 is formed on the thin barrier heterojunction, and includes several spaced apart opening regions. The opening regions include a source opening region, a drain opening region, and a gate opening region. The source 161 and the drain 162 are formed in the source opening region and the drain opening region, respectively.

The passivation layer 15 is capable of inducing high density of positive charges on the surface of the Al(In, Ga)N thin barrier layer 13 and significantly enhances the concentration of the two-dimensional electron gas (2-D Electron Gas, 2-DEG) 14 in the channel except for the gate opening region 18. The passivation layer 15 may be grown and prepared by MOCVD, LPCVD, PECVD, or ALD.

In consideration of the compatibility of the process, the thickness of the passivation layer may be 5 to 200 nm. If it is too thick, the passivation layer may generate large stress. If it is too thin, the passivation layer may not provide enough positive charges to recover 2DEG.

The protective layer 17 is formed on the source 161, the drain 162 and the passivation layer 15. As shown in FIG. 1, in the cross-sectional view of FIG. 1, the passivation layer 15 is spaced apart by the gate opening region 18 to form two parts. A protective layer 17 is formed on a portion of the passivation layer (such as the passivation layer 15 on the left) and the source 161 located in the source opening region. A protective layer 17 is formed on another portion of the passivation layer (such as the passivation layer 15 on the right) and the drain 162 located in the drain opening region. In this way, the gate opening region 18 is exposed to the device surface.

Refer to FIG. 2, when the solution detector 1 of the embodiment is used in the detection of electrolyte solution 2, the electrolyte solution 2 is located in the gate opening region 18 and directly contacts the thin barrier layer 13 to form a contact interface. The electrolyte solution 2 affects interface charges at the contact interface, thereby leading to a change in a concentration of the two-dimensional electron gas 14, and further leading to a significant change in the current between the source 161 and the drain 162, thereby achieving detection of the electrolyte solution 2.

In an embodiment, electrolyte solution detection scenarios include, but not limited to, one of the following detection scenarios: environmental water quality monitoring, detection of a pH value, a concentration or an anion-cation concentration of the electrolyte solution, detection of an ion concentration in food, including an iodine concentration detection, and/or active ions detection in biomedicine.

In an embodiment, the gate opening region is arranged at any position between the source and the drain, which is different from an arrangement in existing enhancement-mode devices, where the gate is arranged closer to the source (relative to the drain). There is no need to consider an arrangement of the position of the gate opening region. The detection performance will not be affected whether the position of the gate opening region is close to the source or the drain, or in the middle, between the source and the drain.

In an embodiment of a solution detector used in an electrolyte solution detection, it may not be necessary to manufacture a gate in a gate opening region, and the gate opening region of the detector is exposed. When the detector is used in electrolyte solution detection, the electrolyte solution is located in the gate opening region and directly contacts the thin barrier layer to form a contact interface. The electrolyte solution affects interface charges at the contact interface, leading to a change in a concentration of a two-dimensional electron gas at the interface of the thin barrier heterojunction, further leading to a significant change in the current between the source and the drain, thereby a highly sensitive solution detection can be achieved. A high density of positive charges may be induced on the surface of the thin barrier layer, and the concentration of the two-dimensional electron gas in the channel except for the gate opening region may be significantly enhanced, by arranging a passivation layer. At the same time, a protective layer formed on the source, the drain and the passivation layer may prevent the electrolyte solution from reacting with electrodes or the passivation layer, and prevent the electrodes from being corroded. Therefore, the device may be reused multiple times and/or the reliability of the device is improved. The detector may be used for monitoring environmental water quality or detecting a pH value, a concentration or an anion-cation concentration of electrolyte solution. The device can have a higher sensitivity than traditional pH test paper and/or may be reused. The device may also be used for detecting an ion concentration in food, such as an iodine concentration, and/or for detecting active ions in biomedicine, and/or the like. The detector may be widely used and reusable, and has a wide range of application prospects.

### Second Embodiment

In a second exemplary embodiment of the present disclosure, a detector based on a gallium nitride-based enhancement-mode device is provided. The detector is a gas detector 1′.

Compared with the first embodiment, the detector of this embodiment is used in detection of a gas such as a hydrogen-containing gas. Structurally, a gate is deposited in the gate opening region. In addition, the gate has a material capable of having a catalytic reaction with the gas and forming a Schottky contact with the thin barrier layer.

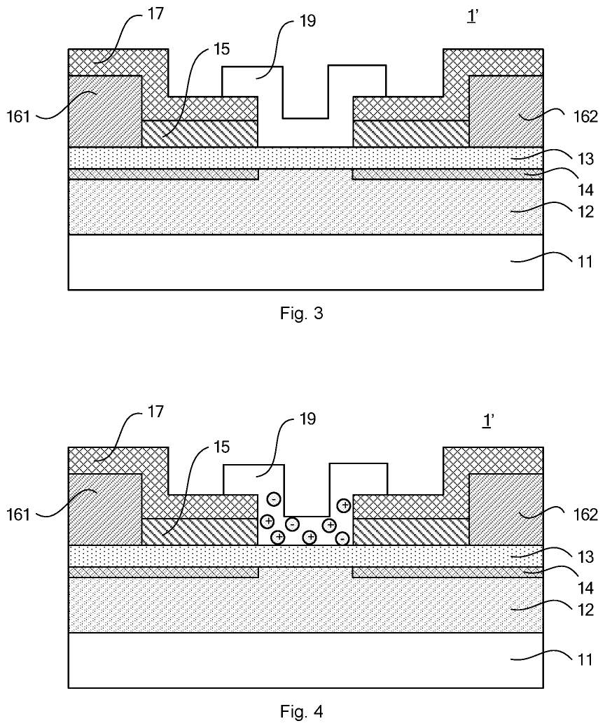

FIG. 3 is a schematic diagram of structure of a detector based on a gallium nitride-based enhancement-mode device according to a second embodiment of the present disclosure. FIG. 4 is a schematic diagram of using the detector shown in FIG. 3 in a concentration detection of a hydrogen-containing gas.

Referring to FIG. 1, FIG. 3, and FIG. 4, the detector based on the gallium nitride-based enhancement-mode device of the embodiment is a gas detector 1′. The gas detector 1′ includes: a substrate 11; a thin barrier heterojunction epitaxial on the substrate and comprising from bottom to top a GaN buffer layer 12 and a thin barrier layer 13; a passivation layer 15 formed on the thin barrier heterojunction and comprising several spaced apart opening regions, the opening regions comprising a source opening region, a drain opening region and a gate opening region; a source 161 formed in the source opening region and in contact with the thin barrier layer 13 at its bottom; a drain 162 formed in the drain opening region and in contact with the thin barrier layer 13 at its bottom; a protective layer 17 formed on the source 161, the drain 162 and the passivation layer 15; and a gate 19 filled in the gate opening region 18 and extending onto the protective layer 17, and in contact with the thin barrier layer 13 at its bottom. The gate 19 has a material capable of having a catalytic reaction with a gas (e.g., a hydrogen-containing gas) and forming a Schottky contact with the thin barrier layer.

In the embodiment, the passivation layer 15 is capable of inducing high density of positive charges on the surface of the Al(In, Ga)N thin barrier layer 13 and significantly enhances the concentration of the two-dimensional electron gas 14 in the channel except for the gate opening region 18. The passivation layer 15 may be grown and prepared by MOCVD, LPCVD, PECVD, or ALD.

In the embodiment, the material, composition, thickness, and other configurations of the thin barrier layer 13 in the thin barrier heterojunction are the same as those of the first embodiment, and are not repeated here.

In the embodiment, the detector may be used to detect a H concentration of a hydrogen-containing gas under extreme environments at high temperature and low temperature. For example, the detector may be used to detect the H concentration of the hydrogen-containing gas at an ambient temperature below 900° C.

Refer to FIG. 4, when the detection is performed, the device is exposed to the hydrogen-containing gas. The H concentration of the hydrogen-containing gas affects charges generated during the catalytic reaction with gate material, and further affects interface charges at a contact interface between the gate 19 and the thin barrier layer 13, leading to a change in a concentration of the two-dimensional electron gas, and further leading to a significant change in the current between the source 161 and the drain 162, thereby detection of the H concentration of the gas is achieved.

In an embodiment, the gate is a monolayer film formed by any one selected from: Pt, IrPt, PdAg, Au, Pd, Cu, Cr or Ni, or a multilayer metal film formed by any combination selected from the foregoing materials.

In an embodiment, the gate opening region 18 is arranged at any position between the source 161 and the drain 162, which is different from the arrangement in existing enhancement-mode devices, where the gate is arranged closer to the source (relative to the drain). There is no need to consider an arrangement of the position of the gate opening region. The detection performance will not be affected whether the position of the gate opening region is close to the source or the drain, or in the middle, between the source and the drain.

In summary, in an embodiment of the detector used for detecting a hydrogen-containing gas, the material of the gate is capable of having a catalytic reaction with hydrogen-containing gas and forming a Schottky contact with the thin barrier layer. The H concentration of the hydrogen-containing gas affects interface charges at the contact interface between the gate and the thin barrier layer, leading to a change in the concentration of the two-dimensional electron gas, and further leading to a significant change in the current between the source and the drain. The detector may detect the H concentration of hydrogen-containing gas under extreme environments at high temperature and low temperature, and presents higher sensitivity and/or repeatability than traditional depleted devices.

### Third Embodiment

In a third exemplary embodiment of the present disclosure, a manufacturing method of the detector shown in the first embodiment is provided.

The manufacturing method of the detector of the present disclosure includes:

Step S31: preparing a substrate;

Step S32: manufacturing a thin barrier heterojunction, which is epitaxial on the substrate and comprises from bottom to top a GaN buffer layer and a thin barrier layer;

Step S33: manufacturing a passivation layer, which is formed on the thin barrier heterojunction and comprises several spaced apart opening regions, the opening regions comprising a source opening region, a drain opening region and a gate opening region;

A two-dimensional electron gas exists at the interface of the thin barrier heterojunction except for the gate opening region.

Step S34: manufacturing a source, which is formed in the source opening region and is in contact with the thin barrier layer at its bottom;

Step S35: manufacturing a drain, which is formed in the drain opening region and is in contact with the thin barrier layer at its bottom;

Step S36: manufacturing a protective layer, which is formed on the source, drain and passivation layer.

In the exemplary embodiment described below, several steps in the various steps of the manufacturing method of the present disclosure may be combined and completed in one step, and a certain step may be split into several processes and interleaved with other steps. All manufacturing methods capable of forming each component of the above-mentioned detector and corresponding connection relationships are within the protection scope of the present disclosure.

In the embodiment, in step S33, a complete passivation layer is first formed, and the formation of the passivation layer is completed in the same epitaxial process as steps S31 to S32, as described in steps a and b in the following embodiments. Next in step S33, the source opening region and the drain opening region are formed in the passivation layer, and steps S34 and S35 are then performed, as described in steps c and d below. A complete protective layer is then formed on above structure, as described in step e. Finally, the protective layer and the passivation layer therebelow are etched to form the gate opening region, as described in step f.

Detailed description is given below with reference to the drawings.

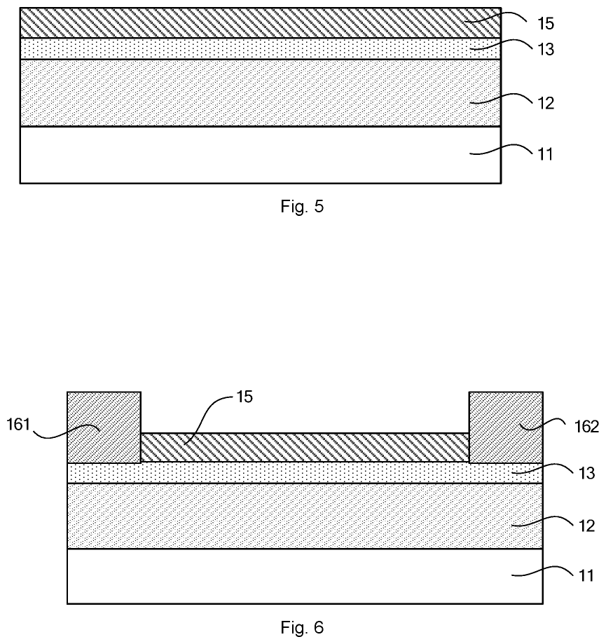

FIG. 5 to FIG. 8 are schematic diagrams of respective steps corresponding to the method for manufacturing the detector shown in the first embodiment according to the third embodiment of the present disclosure.

Refer to FIG. 5 to FIG. 8, the manufacturing method of the detector in the embodiment includes the following steps:

Step a: epitaxial growing, on the substrate 11, a thin barrier heterojunction which comprises from bottom to top a GaN buffer layer 12 and a thin barrier layer 13;

Step b: forming a passivation layer 15 on the thin barrier heterojunction;

The passivation layer 15 may be grown and prepared by MOCVD, LPCVD, PECVD, or ALD.

FIG. 5 is a schematic diagram of the structure after an epitaxial structure is fabricated, and the epitaxial structure includes from bottom to top a substrate, a GaN buffer layer, a thin barrier layer and a passivation layer. The device structure after the implementation of steps a and b is shown in FIG. 5.

Step c: etching the passivation layer 15 to form spaced apart source opening and drain opening regions;

Step d: forming a source 161 in the source opening region, the source 161 in contact with the thin barrier layer 13 at its bottom; and forming a drain 162 in the drain opening region, the drain 162 in contact with the thin barrier layer 13 at its bottom;

FIG. 6 is a schematic diagram of a structure after the passivation layer in the epitaxial structure is etched to form spaced apart source opening and drain opening regions, and a source and a drain are fabricated in the source opening region and the drain opening region, respectively. The device structure after the implementation of steps c and d is shown in FIG. 6.

Step e: forming a protective layer 17 on the source 161, the drain 162 and the passivation layer 15;

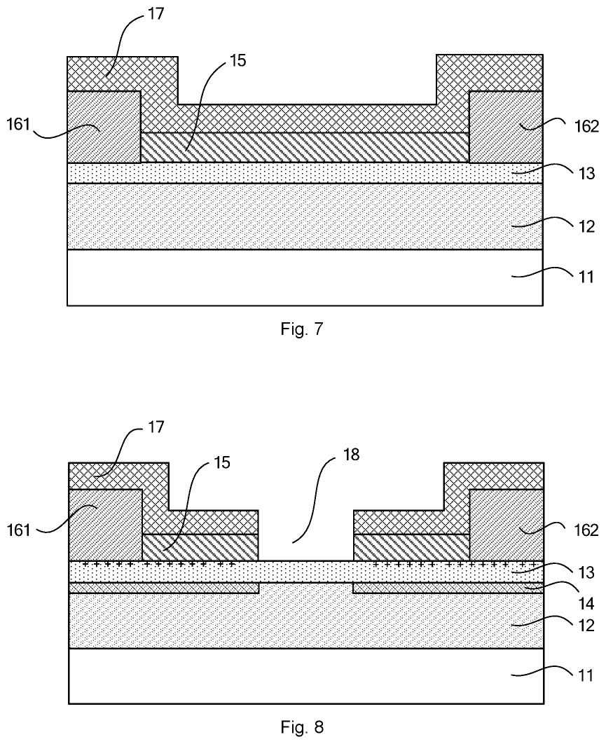

FIG. 7 is a schematic diagram of a structure forming a protective layer on the source, the drain, and the passivation layer. In this step e, a gate opening region has not been formed on the passivation layer 15, therefore the protection layer 17 formed on the source 161, the drain 162, and the passivation layer 15 is a complete protection layer, which is obtained directly by deposition. The device structure after the implementation of step e is shown in FIG. 7.

Step f: etching the protective layer 17 and the passivation layer 15 therebelow in the region between the source 161 and the drain 162, to form a gate opening region 18;

FIG. 8 is a schematic diagram of a structure of etching the protective layer and the passivation layer therebelow in the region between the source and the drain and forming the gate opening region. The device structure after the implementation of step f is shown in FIG. 8. A two-dimensional electron gas 14 exists at the interface of the thin barrier heterojunction except for the gate opening region. The passivation layer 15 may induce a high density of positive charges on the surface of the Al(In, Ga)N thin barrier layer 13 as shown in FIG. 8, thereby significantly enhancing the concentration of the two-dimensional electron gas 14 in the channel except for the gate opening region 18.

When the detector is used in an electrolyte solution detection, the electrolyte solution is located in the gate opening region and directly contacts the thin barrier layer to form a contact interface, interface charges at which are affected by the electrolyte solution, leading to a change in a concentration of the two-dimensional electron gas, and further a change in the current between the source and the drain.

Of course, the above embodiment is only an example. In other manufacturing processes, the order of steps may be adjusted or the manufacturing process may be reasonably arranged. For example, in step S33, after the passivation layer is formed, the spaced apart source opening region, drain opening region, and gate opening region may be simultaneously etched in the passivation layer, and the source and the drain are selectively grown in subsequent steps. A protective layer is then grown on the source, the drain and the passivation layer so that the gate opening region is exposed, that is, the surface of the thin barrier layer 13 below the gate opening region 18 is exposed.

### Fourth Embodiment

In a fourth exemplary embodiment of the present disclosure, a manufacturing method of the detector shown in the second embodiment is provided.

The manufacturing method of the detector of the present disclosure includes:

Step S41: preparing a substrate;

Step S42: manufacturing a thin barrier heterojunction, which is epitaxial on the substrate and comprises from bottom to top a GaN buffer layer and a thin barrier layer;

Step S43: manufacturing a passivation layer, which is formed on the thin barrier heterojunction and comprises several spaced apart opening regions, the opening regions comprising a source opening region, a drain opening region, and a gate opening region, wherein a two-dimensional electron gas exists at an interface of the thin barrier heterojunction except for the gate opening region;

Step S44: manufacturing a source, which is formed in the source opening region and is in contact with the thin barrier layer at its bottom;

Step S45: manufacturing a drain, which is formed in the drain opening region and is in contact with the thin barrier layer at its bottom;

Step S46: manufacturing a protective layer, which is formed on the source, the drain and the passivation layer; and

Step S47: manufacturing a gate, which is filled in the gate opening region and extends onto the protective layer, and the gate is in contact with the thin barrier layer at its bottom and has a material capable of having a catalytic reaction with a gas, such as a hydrogen-containing gas, and forming a Schottky contact with the thin barrier layer.

On the basis of the steps of the third embodiment, the manufacturing method of the detector in this embodiment further includes the step of forming a gate in the gate opening region. Other steps have been described in detail in the third embodiment, and will not be repeated here.

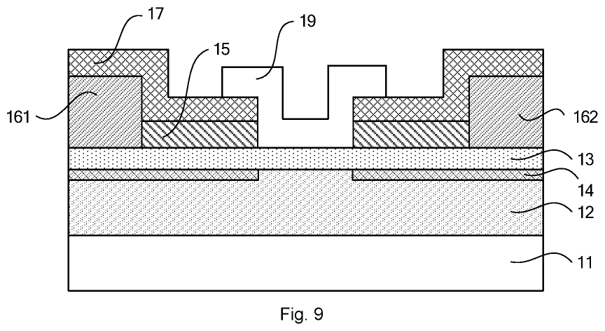

FIG. 9 is a schematic diagram of a structure after a gate is formed in the gate opening region. A gate is formed in the gate opening region as shown in FIG. 9. The gate 19 is filled in the gate opening region 18 and extends onto the protective layer 17, and the gate 19 is in contact with the thin barrier layer 13 at its bottom. The gate 19 has a material capable of having a catalytic reaction with a gas, such as a hydrogen-containing gas, and forming a Schottky contact with the thin barrier layer 13.

In summary, the present disclosure provides a detector based on a gallium nitride-based enhancement-mode device and a manufacturing method thereof. The hydrogen-containing gas and the electrolyte solution affect interface charges at the interface between the gate and the thin barrier layer semiconductor and interface charges at the interface between the solution and the thin barrier layer semiconductor, respectively. This leads to increase or decrease in the 2DEG concentration in the thin barrier heterojunction, thus the current between the source and the drain changes significantly, so that the detection is completed. The detector of the present disclosure may be used in detection of a concentration of a hydrogen-containing gas in harsh environments, environmental water quality monitoring, detection of a pH value and/or a concentration, detection of an ion concentration in food, and/or active ion detection in biomedicine. Compared with a conventional semiconductor detector, the detector based on the GaN-based enhancement-mode device proposed in the present disclosure can have higher detection sensitivity and/or lower power consumption, and the device may be manufactured in one molding and/or used repeatedly.

It should be noted that the directional terms mentioned in the embodiments, such as “upper”, “lower”, “front”, “back”, “left”, “right”, and the like, are only refer to the directions of the drawings, and not used to limit the scope of protection of the present disclosure. The same elements are denoted by the same or similar reference numerals throughout the drawings. Conventional structures or configurations will be omitted when they may cause confusion to the understanding of the present disclosure.

The shapes and sizes of the various components in the drawings do not reflect the true size and proportions, but merely illustrate the contents of the embodiments of the present disclosure. In addition, in the claims, any reference signs placed between parentheses shall not be construed as a limitation.

The specific embodiments described above describe the objectives, technical solutions, and beneficial effects of the present disclosure in further detail. It should be understood that the above are only specific embodiments of the present disclosure and are not intended to limit the present disclosure. Any modifications, equivalents, improvements, and the like, which are made within the spirit and scope of the present disclosure are intended to be included within the scope of the present disclosure.

1. A detector based on a gallium nitride-based enhancement-mode device, comprising:
a substrate;
a thin barrier heterojunction epitaxial on the substrate and comprising from bottom to top a GaN buffer layer and a thin barrier layer, a two-dimensional electron gas existing at an interface of the thin barrier heterojunction;
a passivation layer formed on the thin barrier heterojunction and comprising several spaced apart opening regions, the opening regions comprising a source opening region, a drain opening region and a gate opening region;
a source formed in the source opening region and in contact with the thin barrier layer at its bottom;
a drain formed in the drain opening region and in contact with the thin barrier layer at its bottom; and
a protective layer formed on the source, the drain and the passivation layer,
wherein the detector is configured such that, when the detector is used in an electrolyte solution detection and electrolyte solution is located in the gate opening region and directly contacts the thin barrier layer to form a contact interface, interface charges at the interface are affected by the electrolyte solution, leading to a change in a concentration of the two-dimensional electron gas, and further a change in a current between the source and the drain.

2. The detector of claim 1, wherein the electrolyte solution detection comprises a detection scenario selected from: environmental water quality monitoring, detection of a pH value, a concentration and/or an anion-cation concentration of the electrolyte solution, detection of an ion concentration in food, an iodine concentration detection, and/or active ions detection in biomedicine.

3. The detector of claim 1, wherein the thin barrier layer is formed by a material of Al(In, Ga)N, comprising any one selected from: an AlGaN or AlInN ternary alloy layer, or an AlInGaN quaternary alloy layer; and/or
the thin barrier layer has a thickness of 0-10 nm.

4. The detector of claim 3, wherein:
when the thin barrier layer is an AlGaN ternary alloy layer, an Al composition is fixed and is between 0% and 100%, or the Al composition gradually decreases from y₁% down to x₁%, along from the bottom to the top of the thin barrier layer, where x₁ and y₁ are between 0 and 100;
when the thin barrier layer is an AlInN ternary alloy layer, the Al composition is fixed and is between 75% and 90%, or the Al composition gradually decreases from y₂% down to x₂%, along from the bottom to the top of the thin barrier layer, where x₂ and y₂ are between 0 and 100; or
when the thin barrier layer is an AlInGaN quaternary alloy layer, the respective composition of Al, In, and Ga is fixed or changed.

5. The detector of claim 1, wherein the gate opening region is arranged at any position between the source and the drain, and the position of the gate opening region does not affect detection performance.

6. A detector based on a gallium nitride-based enhancement-mode device, comprising:
a substrate;
a thin barrier heterojunction epitaxial on the substrate and comprising from bottom to top a GaN buffer layer and a thin barrier layer, a two-dimensional electron gas existing at an interface of the thin barrier heterojunction;
a passivation layer formed on the thin barrier heterojunction and comprising several spaced apart opening regions, the opening regions comprising a source opening region, a drain opening region and a gate opening region;
a source formed in the source opening region and in contact with the thin barrier layer at its bottom;
a drain formed in the drain opening region and in contact with the thin barrier layer at its bottom;
a protective layer formed on the source, the drain and the passivation layer; and
a gate filled in the gate opening region and extending onto the protective layer, the gate in contact with the thin barrier layer at its bottom and having a material capable of having a catalytic reaction with a gas and forming a Schottky contact with the thin barrier layer.

7. The detector of claim 6, wherein the detector is used to detect a H concentration of a hydrogen-containing gas.

8. The detector of claim 7, wherein interface charges at an interface between the gate and the thin barrier layer are affected by the H concentration of the hydrogen-containing gas, leading to a change in a concentration of a two-dimensional electron gas, and further a change in a current between the source and the drain.

9. The detector of claim 6, wherein the gate is a monolayer film formed by any selected from: Pt, IrPt, PdAg, Au, Pd, Cu, Cr or Ni, or a multilayer metal film formed by any combination selected therefrom.

10. The detector of claim 6, wherein:
the thin barrier layer is formed by a material of Al(In, Ga)N, comprising any selected from: an AlGaN or AlInN ternary alloy layer, or an AlInGaN quaternary alloy layer; and/or
the thin barrier layer has a thickness of 0-10 nm.

11. The detector of claim 10, wherein:
when the thin barrier layer is an AlGaN ternary alloy layer, an Al composition is fixed and is between 0% and 100%, or the Al composition gradually decreases from y₁% down to x₁%, along from the bottom to the top of the thin barrier layer, where x₁ and y₁ are between 0 and 100;
when the thin barrier layer is an AlInN ternary alloy layer, the Al composition is fixed and is between 75% and 90%, or the Al composition gradually decreases from y₂% down to x₂%, along from the bottom to the top of the thin barrier layer, where x₂ and y₂ are between 0 and 100; or
when the thin barrier layer is an AlInGaN quaternary alloy layer, the respective composition of Al, In, and Ga is fixed or changed.

12. The detector of claim 6, wherein the gate opening region is arranged at any position between the source and the drain, and the position of the gate opening region does not affect detection performance.

13. A method for manufacturing a detector, the method comprising:
manufacturing a passivation layer on a thin barrier heterojunction that is epitaxial on a substrate and comprises from bottom to top a GaN buffer layer and a thin barrier layer, the passivation layer comprising several spaced apart opening regions, the opening regions comprising a source opening region, a drain opening region and a gate opening region;
manufacturing a source, which is formed in the source opening region and is in contact with the thin barrier layer at its bottom;
manufacturing a drain, which is formed in the drain opening region and is in contact with the thin barrier layer at its bottom; and
manufacturing a protective layer, which is formed on the source, the drain and the passivation layer,
wherein a two-dimensional electron gas exists at an interface of the thin barrier heterojunction except for the gate opening region; and
wherein the detector is configured such that, when the detector is used in an electrolyte solution detection and electrolyte solution is located in the gate opening region and directly contacts the thin barrier layer to form a contact interface, interface charges at the interface are affected by the electrolyte solution, leading to a change in a concentration of the two-dimensional electron gas, and further a change in a current between the source and the drain.

14. The method of claim 13, wherein the thin barrier layer is formed by a material of Al(In, Ga)N, comprising any one selected from: an AlGaN or AlInN ternary alloy layer, or an AlInGaN quaternary alloy layer; and/or
the thin barrier layer has a thickness of 0-10 nm.

15. The method of claim 14, wherein:
when the thin barrier layer is an AlGaN ternary alloy layer, an Al composition is fixed and is between 0% and 100%, or the Al composition gradually decreases from y₁% down to x₁%, along from the bottom to the top of the thin barrier layer, where x₁ and y₁ are between 0 and 100;
when the thin barrier layer is an AlInN ternary alloy layer, the Al composition is fixed and is between 75% and 90%, or the Al composition gradually decreases from y₂% down to x₂%, along from the bottom to the top of the thin barrier layer, where x₂ and y₂ are between 0 and 100; or
when the thin barrier layer is an AlInGaN quaternary alloy layer, the respective composition of Al, In, and Ga is fixed or changed.

16. The method of claim 13, wherein the gate opening region is arranged at any position between the source and the drain, and the position of the gate opening region does not affect detection performance.

17. A method for manufacturing a detector, the method comprising:
manufacturing a passivation layer on a thin barrier heterojunction that is epitaxial on a substrate and comprises from bottom to top a GaN buffer layer and a thin barrier layer, the passivation layer comprising several spaced apart opening regions, the opening regions comprising a source opening region, a drain opening region and a gate opening region, a two-dimensional electron gas existing at an interface of the thin barrier heterojunction except for the gate opening region;
manufacturing a source, which is formed in the source opening region and is in contact with the thin barrier layer at its bottom;
manufacturing a drain, which is formed in the drain opening region and is in contact with the thin barrier layer at its bottom;
manufacturing a protective layer, which is formed on the source, the drain and the passivation layer; and
manufacturing a gate, which is filled in the gate opening region and extends onto the protective layer, and the gate is in contact with the thin barrier layer at its bottom and has a material capable of having a catalytic reaction with a gas and forming a Schottky contact with the thin barrier layer.

18. The method of claim 17, wherein the gate is a monolayer film formed by any selected from: Pt, IrPt, PdAg, Au, Pd, Cu, Cr or Ni, or a multilayer metal film formed by any combination selected therefrom.

19. The method of claim 17, wherein:
the thin barrier layer is formed by a material of Al(In, Ga)N, comprising any selected from: an AlGaN or AlInN ternary alloy layer, or an AlInGaN quaternary alloy layer; and/or
the thin barrier layer has a thickness of 0-10 nm.

20. The method of claim 19, wherein:
when the thin barrier layer is an AlGaN ternary alloy layer, an Al composition is fixed and is between 0% and 100%, or the Al composition gradually decreases from y₁% down to x₁%, along from the bottom to the top of the thin barrier layer, where x₁ and y₁ are between 0 and 100;
when the thin barrier layer is an AlInN ternary alloy layer, the Al composition is fixed and is between 75% and 90%, or the Al composition gradually decreases from y₂% down to x₂%, along from the bottom to the top of the thin barrier layer, where x₂ and y₂ are between 0 and 100; or
when the thin barrier layer is an AlInGaN quaternary alloy layer, the respective composition of Al, In, and Ga is fixed or changed.
